(19) United States
(12) Patent Application Publication
(10) Pub. No.: US 2012/0222956 A1
(43) Pub. Date: Sep. 6, 2012

(54) METHOD AND APPARATUS FOR FORMING A CYLINDRICAL TARGET ASSEMBLY

(75) Inventor: Aki Hosokawa, Sunnyvale, CA (US)

(73) Assignee: APPLIED MATERIALS, INC., Santa Clara, CA (US)

(21) Appl. No.: 13/310,337

(22) Filed: Dec. 2, 2011

Related U.S. Application Data
(63) Continuation of application No. 13/281,085, filed on Oct. 25, 2011, now abandoned.
(60) Provisional application No. 61/448,874, filed on Mar. 3, 2011.
(60) Provisional application No. 61/450,842, filed on Mar. 9, 2011.

(51) Int. Cl. C23C 14/34; B08B 5/00; B32B 38/16; B25B 5/14; B32B 37/02; B32B 37/14; B08B 6/00; B24B 1/00

(52) U.S. Cl. 204/298.12; 269/104; 156/294; 156/281; 156/272.2; 156/154

(57) ABSTRACT

Embodiments of the present invention generally comprise a method and apparatus for preparing and bonding a cylindrical sputtering target tube to a backing tube to form a rotary target assembly. In one embodiment, a cylindrical target assembly includes bonding material that has a cylindrical surface and is substantially concentric to the backing tube. In one embodiment, a method for forming a cylindrical target assembly includes filling a gap defined between sputtering target tubes with a spacer. The method also includes removing the spacer after the sputtering target tubes are bonded to a backing tube. In one embodiment, an apparatus for fabricating a cylindrical target assembly comprises of a support tube, two end fittings, and a plurality of clamp elements operable to clamp the support tube between the two end fittings.

### CROSS-REFERENCE TO RELATED APPLICATION

This application is a continuation and claims benefit of U.S. patent application Ser. No. 13/281,085, filed Oct. 25, 2011, which claims benefit of U.S. Provisional Patent Application Ser. No. 61/448,874, filed Mar. 3, 2011, and U.S. Provisional Patent Application Ser. No. 61/450,842, filed Mar. 9, 2011, all of which are incorporated by reference in their entireties.

### BACKGROUND

1. Field

Embodiments of the present invention generally relate to a method and apparatus for preparing and bonding a cylindrical sputtering target to a backing tube to form a cylindrical target assembly.

2. Description of the Related Art

Physical vapor deposition (PVD), or sputtering as it is often called, is one method of depositing material onto a substrate. During a sputtering process, a target may be electrically biased so that ions generated in a process region may bombard the target surface with sufficient energy to dislodge atoms of target material from the target surface. The sputtered atoms may deposit onto a substrate that may be grounded to function as an anode. Alternatively, the sputtered atoms may react with a gas in the plasma, for example nitrogen or oxygen, to deposit onto the substrate in a process called reactive sputtering.

Direct current (DC) sputtering and alternating current (AC) sputtering are forms of sputtering in which the conductive target may be biased to attract ions towards the target. When the sputtering target is non-conductive, radio frequency (RF) sputtering may be used. The sides of the sputtering chamber may be covered with a shield to protect the chamber walls from deposition during sputtering and also to act as an anode in opposite to the biased target to capacitively couple the target power to the plasma generated in the sputtering chamber.

There are two general types of sputtering targets, planar sputtering targets and rotary sputtering target assemblies. Both planar and rotary sputtering target assemblies have their advantages. Rotary sputtering target assemblies may be particularly beneficial in large area substrate processing. Bonding a cylindrical target tube to a backing tube is a challenge in the fabrication of robot rotary target assemblies. Particularly, oxides quickly form on the material used to join the cylindrical target tube to the backing tube prior to the target tube being brought in contact with the backing tube for final assembly. The oxides create a weak joint which may diminish the life and performance of the rotary target assembly. Furthermore, it is desirable during assembly of the sputtering target tube that target segment pieces are sealed and bonded together to prevent excess bonding material from leaking out between the segments. The bonding of target segments may be difficult with known fabrication methods and tools which cannot consistently maintain the concentricity between target tubes. If excessive bonding material leaks out, the bonding material leaves a residue on the target segment pieces. This residue may cause micro arcing between the target segment pieces, thereby making a defective target assembly. Therefore, there is a need in the art for methods and apparatus for producing rotary sputtering targets.

### SUMMARY

One embodiment of the present invention generally includes a method and apparatus for preparing and bonding a cylindrical sputtering target to a backing tube to form a cylindrical target assembly.

In one embodiment, a cylindrical target assembly includes a backing tube, at least two sputtering target tubes, an outer wall diameter of the target tubes, a gap, the gap defined between the target tubes, and a bonding material securing the target tubes to the backing tube. The bonding material forms a cylindrical surface in the gap. The cylindrical surface is substantially concentric to the backing tube and spaced inwards of the outer wall diameter.

In one embodiment, a method for forming a cylindrical target assembly includes wetting an inner surface of at least two sputtering target tubes and an outer surface of a backing tube with a bonding material to form wetted surfaces. The method also includes disposing the sputtering target tube around the backing tube where an interstitial space is defined between the sputtering target tubes and the backing tube. A spacer fills a gap defined between the sputtering target tubes. The sputtering target tubes are bonded to the backing tube by filling the interstitial space with bonding material. The method also includes removing the spacer. By removing the spacer after fabrication of the cylindrical target assembly, micro arcing in the cylindrical target assembly is reduced.

In one embodiment, an apparatus for fabricating a cylindrical target assembly comprises of a support tube having an inside diameter. The apparatus also includes two end fittings having an inner diameter less than the inside diameter of the support tube. Each end fitting has a passage extending from an outer diameter of to the inner diameter. The apparatus further comprises of a plurality of clamp elements operable to clamp the support tube between the two end fittings. The support tube concentrically retains the tubes during bonding of the sputtering target tubes to the backing tubes.

### BRIEF DESCRIPTION OF THE DRAWINGS

So that the manner in which the above recited features can be understood in detail, a more particular description, briefly summarized above, may be had by reference to embodiments, some of which are illustrated in the appended drawings. It is to be noted, however, that the appended drawings illustrate only embodiments of the invention and are therefore not to be considered limiting of its scope, for the invention may admit to other equally effective embodiments.

FIG. 1 is a sectional view of one embodiment of a cylindrical sputtering target assembly according to one embodiment of the invention.

FIG. 2A is a perspective view of a spacer according to one embodiment of the invention.

FIG. 2B is a perspective view of a spacer according to another embodiment of the invention.

FIG. 3A is a partial sectional view of one embodiment of the cylindrical sputtering target assembly of FIG. 1.

FIG. 3B is a partial sectional view of another embodiment of the cylindrical sputtering target assembly of FIG. 1.

FIG. 4 is a front sectional view of an apparatus for fabricating a cylindrical target assembly using a bonding fixture according to one embodiment of the invention.

FIG. 5 is an enlarged partial perspective view of the bonding fixture of FIG. 4 illustrating a collar having two collar segments.

FIG. 6 is a sectional view of two collar segments according to one embodiment of the invention.

FIG. 7 is a partial sectional view of a collar segment interfaced with target tubes of a cylindrical target assembly.

FIG. 8 is a partial sectional view of an end fitting interfaced with a target tube of a cylindrical target assembly.

FIG. 9 is flow diagram of a method of fabricating a cylindrical sputtering target assembly according to one embodiment of the invention.

FIG. 10 is a front view of another embodiment of an apparatus for fabricating a cylindrical target assembly using a bonding fixture.

FIG. 11 is a front view of the bonding fixture of FIG. 10.

FIG. 12 is a sectional view of the bonding fixture of FIG. 10.

FIG. 13 is a partial sectional view of an end fitting of the bonding fixture interfaced with a target tube of a cylindrical target assembly.

FIG. 14 is a flow diagram of a method for fabricating a cylindrical sputtering target assembly according to one embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention generally comprise a cylindrical target assembly and a method and apparatus for bonding a cylindrical sputtering target to a backing tube to form a cylindrical target assembly. The cylindrical sputtering target may be disposed over an outside surface of the backing tube. Oxides are removed from surfaces of the backing tube and cylindrical targets. Melted bonding material is provided to fill an interstitial space defined between the sputtering target and the backing tube. By removing oxides exposed in the interstitial space, the sputtering target and the backing tube are robustly secured by the bonding material. Moreover, the cylindrical target assembly is substantially free of bonding material between and/or on the outside of the sputtering targets, thereby decreasing the probability of arcing which contributes to substrate defects. The sputtering target assembly may be used in a PVD chamber, such as a PVD chamber available from AKT®, a subsidiary of Applied Materials, Inc., Santa Clara, Calif. or a PVD chamber available from Applied Materials Gmbh & Co. KG, located at Alzenau, Germany. However, it should be understood that the sputtering target assembly may have utility in other PVD chambers, including those chambers configured to process large area substrates, substrates in the form of continuous webs, large area round substrates and those chambers produced by other manufacturers.

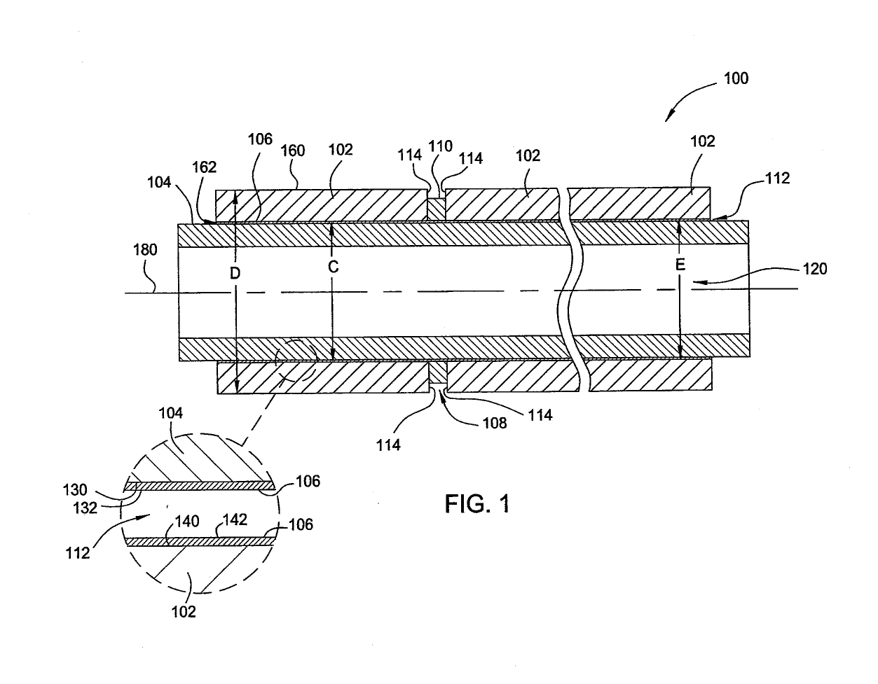

FIG. 1 is one embodiment of a cylindrical sputtering target assembly which may be fabricated using the method and apparatus of one embodiment of the present invention, or by using other suitably adapted apparatus. The target assembly 100 includes two or more sputtering target tubes 102 bonded to a backing tube 104 by a bonding material 106. The bonding material 106 fills an interstitial space 112 defined between the target tubes 102 and the backing tube 104. The target tubes 102 include an inner wall 162, an outer wall 160, an inner wall diameter “C” and an outer wall diameter “D.” The target tubes 102 may be fabricated from sputtering material such as titanium, aluminum, copper, molybdenum, indium gallium zinc oxide (IGZO), indium tin oxide (ITO), aluminum zinc oxide (AZO), or combinations thereof, among others. The backing tube 104 may be fabricated from a rigid material such as stainless steel, titanium, aluminum, and combinations thereof. The bonding material 106 is a material suitable for bonding sputtering targets to backing plates or tubes. Examples of suitable bonding materials include, but are not limited to: indium based bonding material, such as indium and indium alloys. Additionally, within a center 120 of the target assembly 100, one or more magnetrons (not shown) may be provided. The magnetrons may rotate within the center 120 of the target assembly 100. Additionally, cooling mechanisms (also not shown), such as cooling fluid tubes, may be disposed within the center 120 of the cylindrical target assembly 100. The target assembly 100 is rotatable about an axial centerline 180 of the assembly 100 to promote uniform target erosion when in use.

Prior to filling the interstitial space 112 with bonding material 106, surfaces 130, 140 of the target tube 102 and backing tube 104 are wetted with a thin layer of bonding material 106. Surfaces 132, 142 of the bonding material 106 comprising the wetted surfaces 130, 140 may have oxides formed thereon, which are sequentially removed prior to filling the interstitial space 112 with the bonding material 106.

Ends 114 of the target tubes 102 are separated from each other by a gap 108, which may be filled by an optional spacer 110. Adjacent ends 114 of the target tubes 102 may have a mating shape. In the embodiment shown in FIG. 1, the ends 114 are perpendicular relative to the axial centerline 180 of the target tubes 102. It is understood that embodiments of invention allow for other suitable configurations of the ends 114. The spacer 110 is concentric to backing and/or target tubes 104, 102 such that the bonding material 106 filling the interstitial space 112 radially inward of the spacer 110 is also concentric with the target and/or backing tubes 102, 104. The bonding material 106 has an outer diameter “E.”

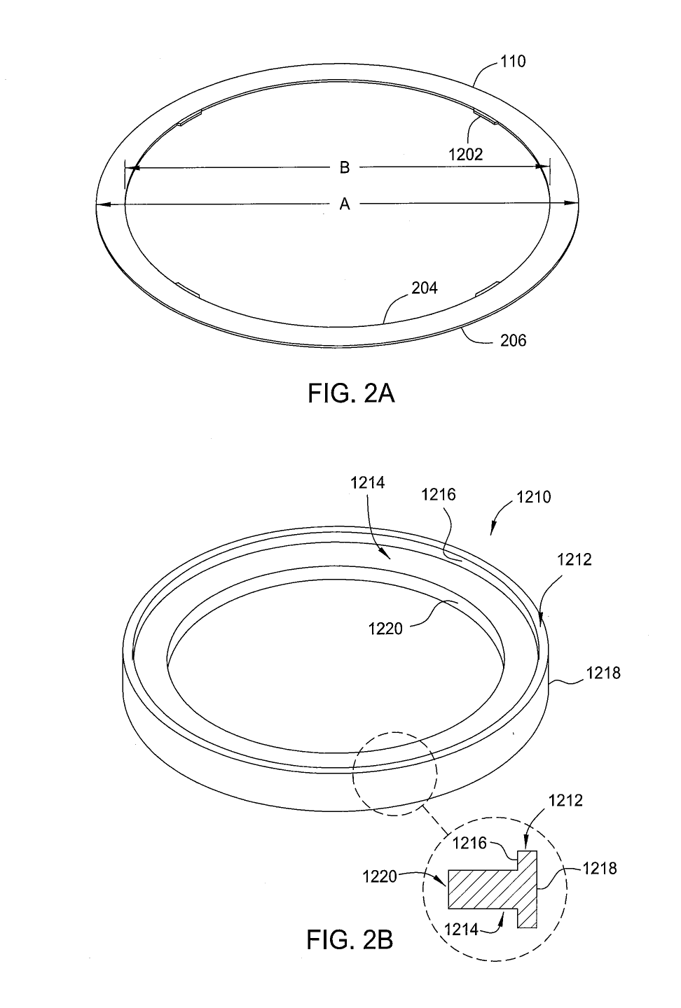

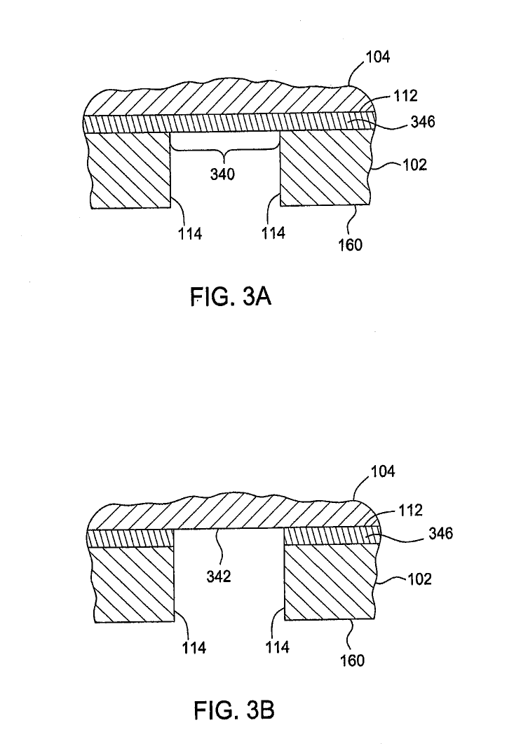

FIG. 2A depicts a perspective view of one embodiment of the spacer 110. The spacer 110 may be a gasket. The spacer 110 may have locating tabs 1202 to hold the spacer 110 concentric to the backing tube 104. The spacer 110 may have an outer wall 1206, an outer wall diameter “A”, an inner wall 1204, and an inner wall diameter “B,” wherein B is less than A. As illustrated in FIG. 3A, in one embodiment, the spacer 110 may be removed after fabrication of the cylindrical target assembly 100. By removing the spacer 110, the bonding material 106 filling the interstitial space 112 is concentric to the target tube 102 to form a substantially smooth cylindrical surface 346 in the gap 108. in other words, the smooth cylindrical surface 346 of the bonding material 106 in the gap 108 is exposed between adjacent target tubes 102 in an as cast condition while being concentric with the target tube 102. The cylindrical surface 346 of the bonding material 106 is substantially concentric to the backing tube 104 and spaced inward of the outer wall diameter D of the target tubes 102. Area 340 is not present when the locating tab 1202 touches the backing tube 104 prior to filling the interstitial space 112 with the bonding material 106. As illustrated in FIG. 3B, when area 340 is not present, one or more indents 342 are formed in the cylindrical surface 346 after removing the spacer 110. Once the spacer 110 is removed, the ends 114 of the target tubes 102 are substantially free of the bonding material 106 used to fill the interstitial space 112. By removing the spacer 110, the need to use tools to remove the bonding material 106 from the ends 114 of the target tubes 102 is eliminated. Thus, the ends 114 of the target tubes 102 have uniform non-interrupted tool marks across the entire surface of the ends 114. As used here, the term “uniform non-interrupted tool marks” is defined as the markings which extend across the entire diameter of the ends 114 of the target tubs 102 created by the tool used to form the ends 114 of the target tubes 102, such as a grinder, saw, or other cutting device tool marks, which are uninterrupted by other types of tool marks utilized to locally remove bonding material after fabrication. The other type of tool marks may include scrapes or gauges created by tools used to remove the bonding material 106 from the ends 114 of the target tubes 102 which always remove a portion of the target material from the ends 114 of the target tubes 102, and thus disturb the tool markings created during forming of the ends 114 of the target tubes 102, i.e., making the tool markings non-uniform. In one embodiment, the spacer 110 may be made of a high temperature plastic such as a polytetrafluoroethylene (PTFE) or a fluoropolymer elastomer. In one embodiment, the gap 108 and the spacer 110 have a width of approximately 0.5 mm. In one embodiment, the inner diameter of the gasket B is less than the inner diameter C of the target tube 102, resulting in the outer diameter E of the bonding material 106 being less than the inner diameter C of the target tubes 102. Thus, the bonding material 106 is recessed below the ends 114 of the target tubes 102, and the ends 114 of the target tubes 102 are free of any bonding material 106.

FIG. 2B is a perspective view of another embodiment of a spacer 1210 which may be used to separate the target tubes 102 of the target assembly 100. The spacer 1210 includes a top surface 1212, a lip 1214, an inner wall 1216, an outer wall 1218, and a lip inner wall 1220. The outer wall 1218 meets the top surface 1212 and the top surface 1212 is adjacent to the inner wall 1216. The inner wall 1216 is adjacent to the lip 1214, wherein the lip 1214 extends to the lip inner wall 1220. The top surface 1212, the lip 1214, the inner wall 1216, and the outer wall 1218 hold the spacer 1210 concentric to the backing tube 104. The lip inner wall 1220 of the spacer 1210 may extend beyond the inner wall 162 of the target tubes 102.

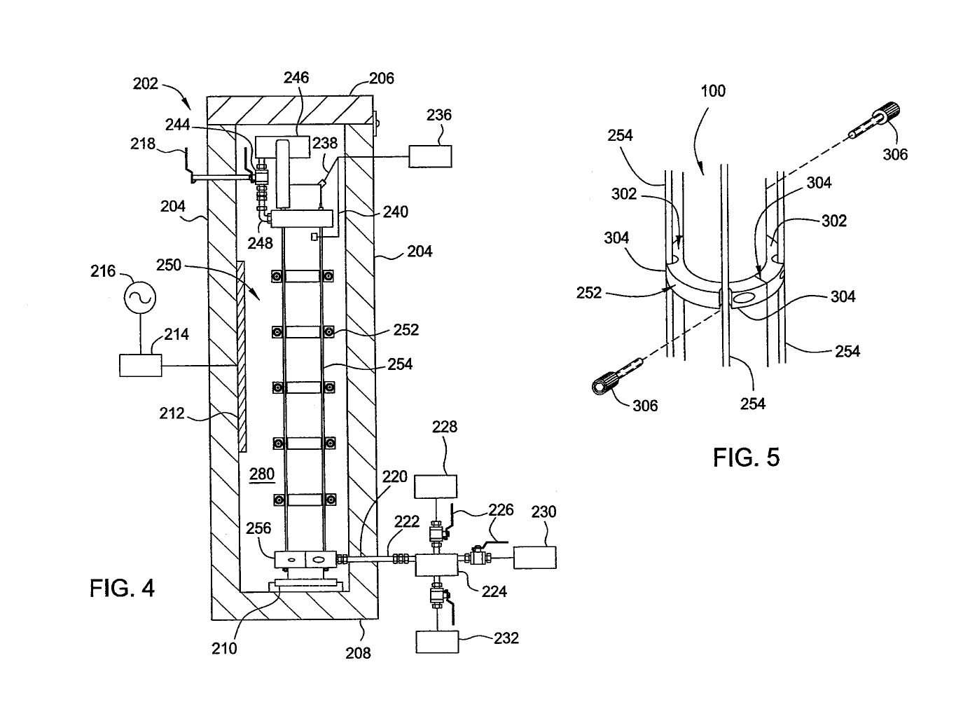

FIG. 4 depicts one embodiment an oven 202 and bonding fixture 250 which may be utilized to fabricate the cylindrical target assembly 100 described in FIG. 1 or other rotary target assembly. The bonding fixture 250 is used to align the target tubes 102 on the backing tube 104 during fabrication of the target assembly 100. The oven 202 generally includes sidewalls 204, a lid 206, and a bottom 208, coupled together to form a processing volume 280 sized to contain the bonding fixture 250 and target assembly 100. In one embodiment, the lid 206 may be removable or pivotally coupled to the sidewalls 204 to selectively allow access to the processing volume 280 of the oven 202 and to the bonding fixture 250.

The oven 202 further includes a locating fixture 210 which is utilized to locate the target assembly 100 within the oven 202 in a substantially vertical orientation. In the embodiment shown in FIG. 4, the locating fixture 210 is coupled to the bottom 208 of the oven 202. The locating fixture 210 is sized to engage an end of the backing tube 104 The locating fixture 210 may optionally include or be coupled to a motor (not shown) such that the backing tube 104 of the target assembly 100 may be rotated relative to the target tubes 102 while in the oven 202.

The oven 202 further includes a heater 212 is operable to elevate the temperature of the target assembly 100 to at least the melting point of the bonding material 106. In one embodiment, the heater 212 may elevate and maintain the temperature at a temperature greater than 200 degrees Celsius. The heater 212 may be a resistive heater, a radiant heater, a forced convection heater or other suitable heater. In the embodiment depicted in FIG. 4, the heater 212 is a resistive heater that is coupled to a controller 214 and a power source 216 utilized to control the temperature within the processing volume 280 of the oven 202.

The bonding fixture 250 includes a plurality of collars 252, a plurality of rods 254, and two end fittings 256. The rods 254 are utilized to urge the end fittings 256 towards each other to hold the target tubes 102 on the backing tube 104. The end fitting 256 utilized near the top of the oven 202 is coupled by a conduit 248 to a hopper 246 through an inlet valve 244. The hopper 246 has a volume sufficient to hold enough bonding material to bond the target tube 102 to the backing tube 104. In some embodiments, the hopper 246 may be sized to hold additional bonding material to perform one embodiment of an oxide removal operation as later described. The inlet valve 244 has at least an open position and a closed position. The closed position of the inlet valve 244 isolates and prevents bonding material from flowing from the hopper 246. The open position of the inlet valve 244 allows the bonding material in the hopper 246 to flow into the interstitial space 112 defined between the target tubes 102 and the backing tube 104 through the end fitting 256. The inlet valve 244 may be operated through the side wall 204 by an inlet valve control 218 located exterior to the oven 202. In certain embodiments, the inlet valve 244 may be a three way valve that includes a vent position that selectively couples the interstitial space 112 defined between the target tubes 102 and the backing tube 104 to the processing volume 280 within the oven 202. In some embodiments, the vent position of the three-way valve may couple the interstitial space 112 to a facilities or other exhaust to control the gas content within the oven 202.

In the embodiment shown, the end fitting 256 located at the bottom of the oven 202 is coupled to a conduit 222 which extends through a passage 220 formed in the sidewalls 204 to a manifold 224 located exterior to the oven 202. The manifold 224 is coupled to a plurality of shutoff valves 226. One shutoff valve 226 selectively couples the manifold 224 to a vacuum source 228. A second shutoff valve 226 selectively couples the manifold 224 to a gas source 230. A third shutoff valve 226 selectively couples the manifold 224 to a collection bin 232. The shutoff valve 226 may be set to an open position that couples the vacuum source 228 to the interstitial space 112 defined between the target tube 102 and the backing tube 104 to assist in drawing the bonding material 106 into the interstitial space 112. By drawing the bonding material 106 into the interstitial space 112 with the vacuum source 228, the amount of air bubbles or pockets formed in the bonding material 106 may be reduced. The gas source 230 may be utilized to provide a purge gas into the interstitial space 112 during fabrication of the target assembly 100. The collection bin 232 is utilized for capturing bonding material in embodiments where flushing is used in removing an oxidation layer of the bonding material during fabrication of the target assembly 100, as described below.

The oven 202 may optionally include a power source 236 having leads 238, 240 extending into the processing volume 280 of the oven 202. In one embodiment, the power source 236 may include a DC power source. The leads 238, 240 are adapted to connect to the target assembly 100. In the embodiment shown, one lead 238 is adapted to couple to the target tube 102 and the opposite lead 240 is adapted to couple to the backing tube 104. In this manner, the DC power source may place a DC potential across the target tubes 102 and backing tube 104, such that a DC current removes oxides as described below.

FIGS. 5-7 depict one embodiment of the collar 252 of the bonding fixture 250. The collar 252 includes two collar segments 302 which are fastened together using fasteners 306. In the embodiment shown, one collar segment 302 has a clearance hole 402 which aligns to a threaded hole 404 in the opposing collar segment 302. In this manner, the fasteners 306 may be used to clamp the two collar segments 302 together around the target tubes 102. Each of the collar segments 302 has two notches 304 which are utilized to locate the rods 254. The collar segments 302 include two o-ring glands 552 that secure o-rings 554. The o-rings 554 are compressed against the target tube 102 upon assembly of the collar segments 302. In the embodiment shown in FIG. 5, each o-ring 554 is positioned on either side of the gap 108 defined between adjacent target tubes 102 so that bonding material 106 present in the interstitial space 112 may not leak out through the gap 108 and into the oven 202.

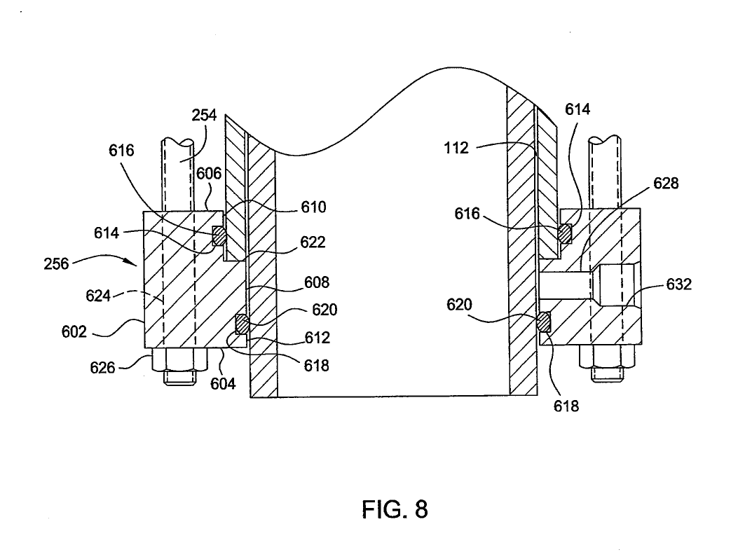

FIG. 8 depicts one embodiment of the end fitting 256 shown in FIG. 4. The end fitting 256 includes an outer diameter 602, an outside edge 604, an inside edge 606, and a stepped inner diameter 608. Although the end fitting 256 depicted in FIG. 8 is the end fitting 256 located at the bottom of the oven 202, it is understood that the other end fitting 256 at the top of the oven 202 is similarly configured. The end fittings 256 are mounted and arranged within oven such that the inside edges 606 of the end fittings 256 face each other.

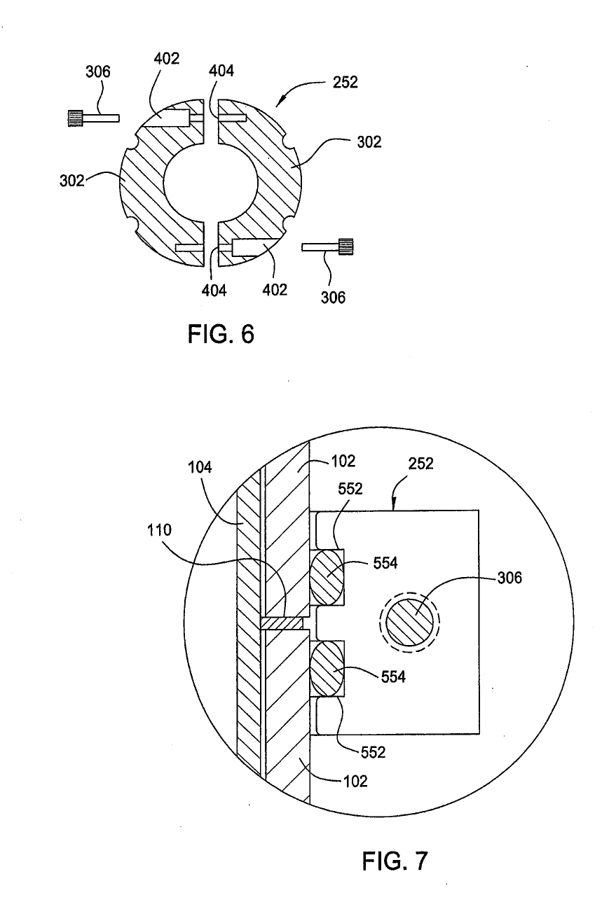

The stepped inner diameter 608 includes a large inner diameter 610, a small inner diameter 612, separated by a step 622. The large inner diameter 610 is dimensioned to allow the target tube 102 to slide inside. The large inner diameter 610 includes an o-ring gland 614 which accommodates an o-ring 616. The o-ring 616 provides a seal between the end fitting 256 and the target tube 102. The small inner diameter 612 includes an o-ring gland 618 that accommodates an o-ring 620. The small inner diameter 612 is dimensioned to allow the backing tube 104 to slide inside while the o-ring 620 provides a seal between the backing tube 104 and the end fitting 256. The step 622 provides a substantially horizontal surface to locate the end fitting 256 against the distal end of the target tube 102. The end fittings 256 additionally include a plurality of rod holes 624 which accept the rods 254. The rod holes 624 are shown in phantom in FIG. 6 but are understood to align with the notches 304 formed in the collar segments 302. Nuts 626 are engaged on the distal end of the rods 254 and may be tightened against the outside edge 604 of the end fitting 256 to compress the target tubes 102 between the steps 622 of the opposing end fittings 256.

The end fittings 256 additionally include a passage 628 that extends between the inside diameter 608 and the outside diameter 602 of the end fitting 256. The passage 628 terminates in a port 632 that facilitates coupling to the conduit 222 or 248 (seen in FIG. 4). The passage 628 is located between the o-ring glands 614, 618 such that the passage 628 is fluidly coupled to the interstitial space 112 defined between the target tubes 102 and backing tube 104. The o-rings 616, 620 seal opposite ends of the interstitial space 112 so that bonding material 106 flowing through the interstitial space 112 does not leak into the processing volume 280 of the oven 202. Referring additionally to FIG. 4, the port 632 of the lower end fitting 256 is coupled to the conduit 222 which extends through the passage 220 to the manifold 224. The port 632 formed in the upper end fitting 256 is coupled through the conduit 248 to the hopper 246.

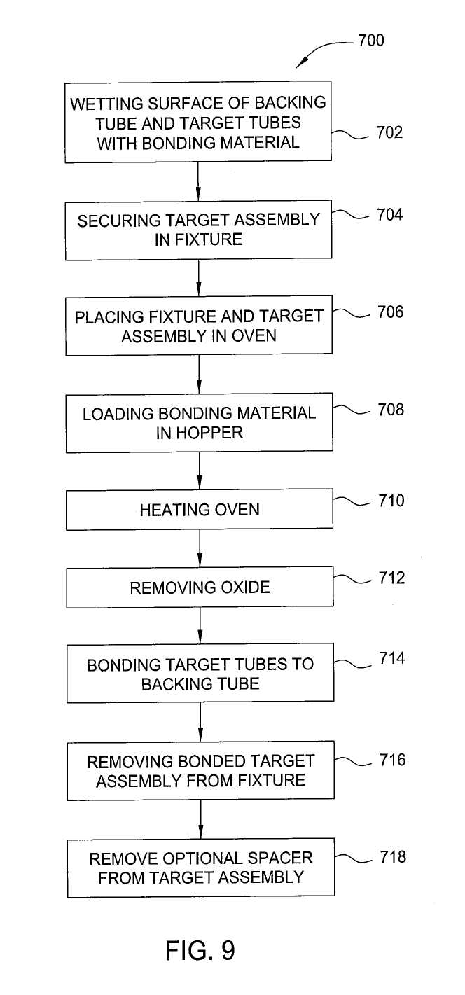

FIG. 9 is a flow diagram of one embodiment of a method for fabricating a target assembly utilizing the oven and fixture described in FIG. 4-8. It is understood that the method may be practiced utilizing other apparatuses, and it is also understood that the apparatus shown may be utilized with other methods for preparing and bonding a cylindrical sputtering target assembly.

The method 700 begins at step 702 by wetting an outer surface of the backing tube 104 and an inner surface of the target tubes 102 with bonding material 106. In one embodiment, the target tubes 102 and the backing tube 104 may be heated to a sufficient temperature to allow application of the bonding material 106 to wet an outer surface of the backing tube 104 and an inner surface of the target tubes 102. In some cases, after the wetting, an oxidation layer may form on the wetted surface while the target tubes 102 and backing tube 104 upon cooling, as described further below. In one specific example, where a target tube comprising ITO is bond to a backing tube using indium, an equilibrium chemical reaction can occur (i.e., 2In₂O₃ [symbol] 4In+3O₂) which releases oxygen and creates an oxide layer on the surface of the indium wetting the backing tube and target tube. The oxidation layer may lead to defects in the target assembly 100 if not removed, such as an increased tendency for the target tubes 102 to crack or a degradation of the bond between the target tubes 102 and backing tube 104. The oxidation layer may be removed by subsequent processes according to one embodiment of the present invention described below.

At step 704, the target assembly 100 is secured within the bonding fixture 250 or other suitable fixture. In the embodiments shown in FIGS. 1-8, the target tubes 102 are slid onto the backing tube 104. The collars 252 are positioned to span the appropriate gaps 108 between target tubes 102, and the fasteners 306 are engaged with the corresponding threaded holes 404 to urge the collar segments 302 together. The end fittings 256 are fitted onto each of target tubes 102 at the end of the target assembly 100. The rods 254 are installed within the notches 304 of the collars 252. Nuts 258 are tightened to clamp the target tubes 102 and spacers 110 together between the end fittings 256.

At step 706, the bonding fixture 250 and the target assembly 100 held therein are placed into the oven 202. In the embodiment shown in FIG. 4, the backing tube 104 is interfaced with the locating fixture 210 to locate the bonding fixture 250 and target assembly 100 within the oven 202. The hopper 246 is attached to the end fitting 256 positioned at the top of the oven 202 by coupling the inlet conduit 248 to the port 632. At the bottom of the oven 202, the conduit 222 is fitted to the lower end fitting 256 by securing the inlet conduit 222 to port 632 of the lower end fitting 256.

At step 708, a sufficient amount of bonding material to fill the interstitial space 112 between the target tubes 102 and the backing tube 104 is loaded into the hopper 246. Additional bonding material beyond the amount necessary to fill the interstitial space 112 may be disposed in the hopper 246 when necessary. In one embodiment, about 100 percent to 500 percent additional bonding material may be loaded into the hopper 246. The lid 206 of the oven 202 is closed to seal the bonding fixture 250 within oven 202.

At step 710, the heater 212 elevates and maintains the temperature within the oven 202 to a predefined temperature. In one embodiment, the heater 212 raises the temperature within the oven 202 above the melting point of the bonding material 106. For example, the heater 212 may maintain the oven 202 at a temperature greater than 150 degrees Celsius, such as 180 degrees Celsius. It is contemplated that the temperature will be selected commiserate with the melting temperature of the bonding material 106.

At step 712, an oxide removal procedure is performed to remove oxides present on the wetted surfaces exposed to the interstitial space 112 defined between the target tubes 102 and the backing tube 104. The oxide removal procedure may be performed in a variety of manners, exemplary embodiments of which are described below. The oxidation layer removal methods and techniques generally remove the oxidation layer which forms on the bonding material 106 applied to inner surface 140 of the target tubes 102 and the outer surface 130 of the backing tube 104 during the wetting described above. The removal of the oxidation layer during the fabrication of the cylindrical target assembly 100 results in substantially oxide-free wetted surfaces, improves the bonding of the target tubes 102 to the backing tube 104, reduces cracking of the target tubes 102 during the lifetime of the target assembly 100, and raises the durability of the target assembly 100. The details of the oxidation removal procedure will be described in further detail below.

After the oxide removal procedure at step 712, the target tubes 102 are bonded to the backing tube 104 by opening the inlet valve 244 to allow bonding material in the hopper 246 to fill the interstitial space 112 between target tubes 102 and the backing tube 104, at step 714. In one embodiment, the vacuum source 228 is fluidly coupled to the interstitial space 112 through the lower end fitting 256 to draw a vacuum and pull the bonding material 106 into the interstitial space. Once the interstitial space 112 has been filled with bonding material 106, the inlet valve 244 may be closed and the oven 202 is permitted to cool. After the target assembly 100 has sufficiently cooled, the oven 202 is opened and the bonding fixture 250 and target assembly 100 are removed from the oven 202, at step 716. The bonding fixture 250 is dismantled and removed from the bonded cylindrical target assembly 100, and the target assembly 100.

As described above, the oxide removal process at step 712 may be performed using a variety of methods and manners. In one embodiment, the oxide removal process step 712 may be performed by applying an electrical current across the target tubes 102 and backing tube 104 during the bonding at step 714. Optionally, a DC current can be applied during the wetting at step 702 such that the bonding material wetting the inner surface of the target tube 102 and/or backing tube 104 is applied with minimal oxide formation.

DC power applied across the target tubes 102 and backing tube 104 creates an indium oxide reduction reaction (i.e., O₂+In [symbol] In₂O₃). In one embodiment, an electrical bias potential of at least 12 Volts and an electrical current of at least 10 Amperes may be applied across the target tubes 102 and backing tube 104 using the power source 236 and leads 238, 240 coupled to the target assembly 100. In an alternative embodiment, the amount of electrical current provided to the target assembly 100 may be predetermined based on the configuration of the target assembly 100 and Faraday's laws of electrolysis. An end point of this oxide removal method may be determined by monitoring the electrical current passing through the target assembly 100. A rise in current is generally indicative of the oxide removal, and an inability of the target assembly 100 to hold a charge generally indicates a substantially oxide-free wetted surface. In an embodiment where the target assembly comprises ITO bonded by indium, the application of electrical current may be controlled using the below formula:

$$\frac{m}{M} = \frac{I * t}{z * F}$$

wherein m is equal to the weight of indium oxide (g), M is equal to the gram per mole of indium oxide (i.e., 277.64 g/mol), I is equal to the electrical current provided (A), t is equal to the time required for reduction (sec), z is a constant (i.e. +3 for indium), F is the Faraday constant (i.e., 9.65×10⁴ A sec/mol), and p is the specific weight of indium oxide (i.e., 7.18 g/cm³).

In another embodiment, the oxide removal process at step 714 may be performed using a hydrogen reduction reaction (i.e., H₂+O₂=>H₂0) on the wetted surface. A hydrogen or hydrogen-containing gas mixture (e.g., H₂) may be provided from the gas source 230 into the interstitial space 112 of the target assembly 100. In one embodiment, the gas mixture comprises less than 3% hydrogen gas by weight. In another specific example, the gas mixture contains a predetermined mixture of gases comprising 2% hydrogen and 8% argon by weight.

To perform the oxide removal process at step 714 using hydrogen reduction reaction, the target assembly 100 may be heated by the heater 212 to a temperature suitable to promote the hydrogen reduction reaction. In one embodiment, the heater 212 may elevate the temperature of the oven 202 to about 100 to 200 degrees Celsius. Then the interstitial space 112 of the target assembly 100 may be pumped down to a pressure of about 1 Torr by opening the shutoff valve 226 and utilizing the vacuum source 228. The gas source 230 then provides the hydrogen or hydrogen-containing gas mixture to the interstitial space 112 to remove oxides present on the wetted surfaces of the backing tube 104 and target tubes 102 exposed to the interstitial space 112. The hydrogen or hydrogen-containing gas mixture may be purged from the interstitial space 112 and a new hydrogen or hydrogen-containing gas mixture introduced into the interstitial space 112 using the sources 228, 230, repeatedly, until any oxide layers are removed completely. Optionally, the interstitial space 112 may be vented through the valve 244 to allow the hydrogen gas mixture to be introduced from the gas source 230. The end point of the oxide removal process may be determined by monitoring water vapor escaping the target assembly 100. A reduction in water vapor is indicative of less oxide remaining within the target assembly 100, whereas an absence of water vapor indicates a substantially oxide-free bonding material 106 comprising the wetted surfaces.

In another embodiment, the oxide removal process at step 712 may be performed by flushing the interstitial space 112 between the target tubes 102 and backing tube 104 with additional bonding material 106. The heater 212 elevates and maintains the temperature of the oven 202 above the melting point of the bonding material 106. The inlet valve 244 is selected to an open position to allow flow of flushing bonding material from the hopper 246 into the interstitial space 112. The flushing bonding material exits the target assembly 100 through the passage 628 of the end fitting 256 at the lower end of the oven 202. The shutoff valve 226 is operated to permit the flushed bonding material to flow through the passage 628, through the manifold 224 and into the collection bin 232 where the flushed bonding material is collected and disposed of. In one embodiment, the interstitial space 112 between the target tubes 102 and the backing tube 104 may be flushed at least four times to remove oxides from the wetted surfaces of the target tubes 102 and backing tube 104. After the wetted surfaces 132, 142 exposed to interstitial space 112 have been flushed, the method 700 can proceed to the bonding at step 714 described above.

In yet another embodiment, the oxide removal process at step 712 may be performed by mechanically rotating the target tube relative to be backing tube 104 to remove the oxides from the wetted surfaces 132, 142 by friction. The target tube 102 may be rotated relative to the backing tube 104 using the motorized locating fixture 210 to create a viscous shear force which removes the oxide from the wetting surface. It is understood that oxide removal by mechanical rotation of the target tube assembly 100 may be performed prior to or during the bonding at step 714 described above. It is further understood that any of oxide removal techniques described above may be utilized alone or in combination to effectively remove oxidation layers from the target assembly 100.

In another embodiment, the optional spacer 110 may be removed from the target tube assembly 100 at step 718. The removal of the optional spacer 110 results in the ends 114 of the target tubes 102 being substantially free of any bonding material 106. Ends 114 of target tubes 102 with substantially no bonding material 106 substantially reduces micro arcing between the target tubes 102. Furthermore, removal of the optional spacer 110 eliminates the need to remove the bonding material 106 from the ends 114 of the target tubes 102. Thus, the ends 114 of the target tubes 102 are free of any tool-marks which may lead to chipping of the target tubes 102 during use.

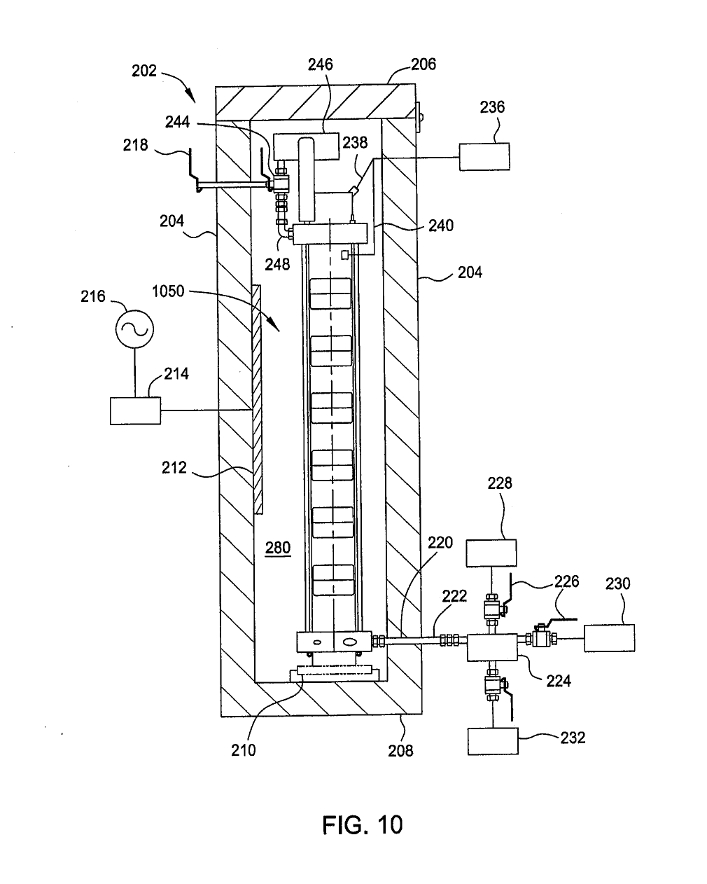

FIG. 10 depicts another embodiment of an oven 202 and a bonding fixture 1050 which may be utilized to fabricate the cylindrical target assembly 100 described in FIG. 1 or other rotary target assemblies.

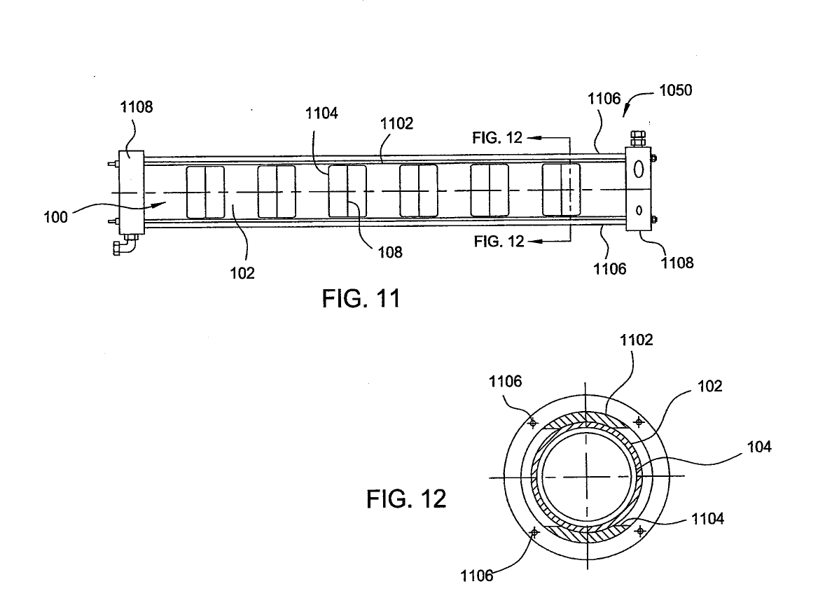

FIGS. 11 and 12 depict one embodiment of the bonding fixture 1050. The bonding fixture 1050 includes a support tube 1102, a plurality of clamp elements 1106, and two end fittings 1108. The support tube 1102 is disposed around the target tubes 102 in a slip-fit or close-fit arrangement to concentrically align the target tubes 102 along the backing tube 104 with the optional spacers 110 therebetween. The support tube 1102 further ensures a uniform distance across the interstitial space 112 defined between the inner surface of the target tubes 102 and the outer surface of the backing tube 104. The internal diameter of the support tube 1102 is selected to have a slip-fit arrangement relative to the target tubes 102. The clamp elements 1106 are used to urge the end fittings 1108 towards each other to axially compress the target tubes 102 on the backing tube 104. The compression of the target tubes 102 squeezes the optional spacers 110 between adjacent target tubes 102 to create a seal which substantially prevents excess bonding material from escaping between from the gaps 108 during fabrication of the target assembly 100. The support tube 1102 generally has an axial length less that of the total length of the target tubes 102 and the spacers 110. In one example, the support tube 1102 has an axial length equal to the total axial length of the target tubes 102 and the spacers 110 minus a distance sufficient to allow compression of the target tubes 102 and spacers 110 by the end fittings 1108. The support tube 1102 may be fabricated from a material selected to have a coefficient of thermal expansion larger than that of the target tubes 102 and backing tube 104 so that the support tube 1102 does not crush the target assembly 100 when heated by the oven 202. In one embodiment, the support tube 1102 may be fabricated from aluminum or polyvinyl chloride (PVC).

The support tube 1102 includes a plurality of evenly spaced windows 1104 formed throughout the length of the support tube 1102. The windows 1104 are configured to permit views of the gaps 108 of the target assembly 100 when installed in the bonding fixture 1050. As shown, the windows 1104 are formed in locations corresponding to the gaps 108 of the target assembly 100 to provide a window for each of the gaps 108. In the embodiment shown in FIG. 12, the windows 1104 are formed through opposite sides of the support tube 1102. The windows 1104 allow the alignment of the target tubes 102 and spacers 110 to be inserted after compression within the bonding fixture 1050 prior to application of the bonding materials, thereby ensuring better fabrication results. Alternatively, the spacer 1210, or other suitable spacers may be utilized.

In the embodiment shown in FIG. 10, the end fitting 1108 located at the bottom of the oven 202 is coupled to a conduit 222 which extends through a passage 220 formed in the sidewalls 204 to a manifold 224 located exterior to the oven 202.

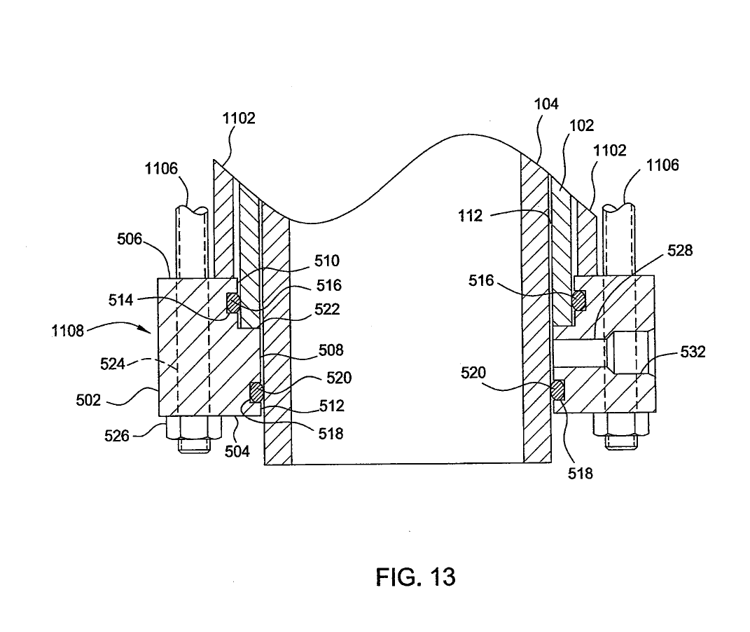

FIG. 13 depicts one embodiment of the end fitting 1108 shown in FIGS. 10-12. The end fitting 1108 includes an outer diameter 502, an outside edge 504, an inside edge 506, and a stepped inner diameter 508. Although the end fitting 1108 depicted in FIG. 13 is the end fitting located at the bottom of the oven 202 in FIG. 10, it is understood that the other end fitting 1108 at the top of the oven 202 is similarly configured. The end fittings 1108 are mounted and arranged within the oven 202 such that the inside edges 506 of the end fittings 1108 face each other.

The stepped inner diameter 508 includes a large inner diameter 510, a small inner diameter 512, separated by a step 522. The large inner diameter 510 is dimensioned to allow a target tube 102 to slide inside. The large inner diameter 510 includes an o-ring gland 514 which accommodates an o-ring 516. The o-ring 516 provides a seal between the end fitting 1108 and the target tube 102. The small diameter 512 also includes an o-ring gland 518 that accommodates an o-ring 520. The small inner diameter 512 is dimensioned to allow the backing tube 104 to slide inside while the o-ring 520 provides a seal between the backing tube 104 and the end fitting 1108. The small inner diameter 512 has a diameter less than an inside diameter of the support tube 1102. The step 522 provides a substantially horizontal surface to locate the end fittings 1108 against the distal end of the target tubes 102.

The target tubes 102 are clamped between the end fittings 1108 using the clamp elements 1106. The clamp elements 1106 may be a flat bar, threaded rod, strap, clamp mechanism, pneumatic or hydraulic cylinder, turnbuckle or other clamping mechanism. In the embodiment depicted in FIG. 13, the clamp elements 1106 are threaded rods. The end fittings 1108 additionally include a plurality of rod holes 524 which accept the clamp elements 1106. Nuts 526 are engaged on the distal ends of the clamp elements 1106 and may be tightened against the outside edge 504 of the end fittings 1108 to compress the target tubes 102 between the steps 522 of the opposing end fittings 1108. In one embodiment, the target tubes 102 are compressed by the steps 522 sufficient to create a seal between the gaps 108 by the spacers 110 such that bonding material 106 flowing in the interstitial space 112 does not leak into the processing volume 280. In the embodiment shown, the support tube 1102 is disposed on the insider edge 506 of the end fittings 1108.

The end fittings 1108 additionally include a passage 528 that extends between the inside diameter 508 and the outside diameter 502 of the end fitting 1108. The passage 528 terminates in a port 532 that facilitates coupling to the conduit 222 or 248 (seen in FIG. 10). The passage 528 is located between the o-ring glands 514, 518 such that the passage 528 is fluidly coupled to the interstitial space 112 defined between the target tubes 102 and backing tube 104. The o-rings 516, 520 seal opposite ends of the interstitial space 112 so that bonding material 106 flowing through the interstitial space 112 does not leak into the processing volume 280 of the oven 202. Referring additionally to FIG. 10, the port 532 of the lower end fitting 1108 is coupled to the conduit 222 which extends through the passage 220 to the manifold 224. The port 532 formed in the upper end fitting 1108 is coupled through the conduit 248 to the hopper 246.

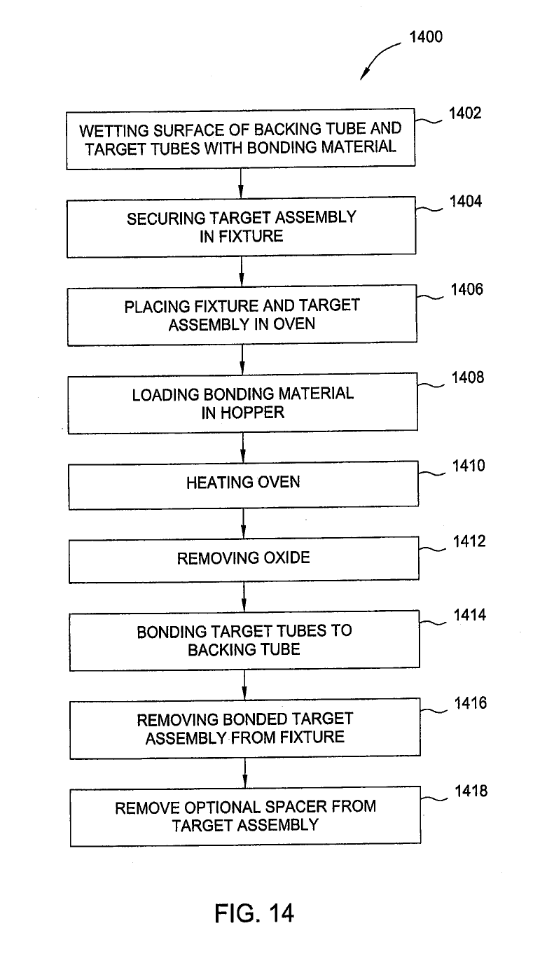

FIG. 14 is a flow diagram of one embodiment of a method 1400 for fabricating a target assembly utilizing the oven 202 and bonding fixture 1050 described in FIGS. 10-13. It is understood that the method may be practiced utilizing other apparatuses, and it is also understood that the apparatus may be utilized with other methods for preparing and bonding a cylindrical sputtering target assembly.

The method 1400 beings at step 1402 by wetting the surface of the backing tube 104 and the target tubes 102 with bonding material 106. In one embodiment, the target tubes 102 and backing tube 104 may be heated to a sufficient temperature to allow application of the bonding material 106 to wet an outer surface of the backing tube 104 and an inner surface of the target tubes 102.

At step 1404, the target assembly 100 is secured within the bonding fixture 1050 or other suitable fixture, as illustrated. In the embodiments shown in FIGS. 10-13, the target tubes 102 and spacers 110 are alternatively slid onto the backing tube 104. The ends 114 of the target tubes 102 are oriented to align together. The support tube 1102 is then slid over the target tubes 102 to create a slip-fit or a close fit over the target tubes 102. In one embodiment, the support tube 1102 maintains the interstitial space 112 between the target tubes 102 and the backing tube 104 uniformly at around 1 mm±0.2 mm. In one embodiment, the support tube 1102 is disposed over the target tubes 102 such that the windows 1104 of the support tube 1102 are aligned over the gaps 108 of the target assembly 100 such that the ends 114 of the target tubes 102 may be seen through the bonding fixture 1050. The end fittings 1108 are fitted onto each of the target tubes 102 at the end of the target assembly 100. The clamp elements 1106 are installed in the threaded holes 524 of the end fittings 1108. The nuts 526 are tightened to clamp and compress the target tubes 102 together between the end fittings 1108 with a sufficient enough force to create a seal between the spacers 110 and the target tubes 102. The alignment of the ends 114 and spacers 110 are checked through the windows 1104 to ensure proper alignment of the target tubes 102 after compression and prior to the introduction of the bonding material to minimize defects.

At step 1406, the bonding fixture 1050 and the target assembly 100 held therein are placed into the oven 202. In the embodiment shown in FIG. 10, the backing tube 104 is interfaced with the locating fixture 210 to locate the bonding fixture 1050 and the target assembly 100 within the oven 202. The hopper 246 is attached to the end fitting 1108 positioned at the top of the oven 202 by coupling the inlet conduit 248 to the port 532. At the bottom of the oven 202, the conduit 222 is fitted to the lower end fitting 1108 by securing the inlet conduit 222 to port 532 of the lower end fitting 308.

At step 1408, an amount of bonding material 106 sufficient to fill the interstitial space 112 between the target tubes 102 and the backing tube 104 is loaded into the hopper 246. Additional bonding material may be disposed in the hopper 246 when necessary. The lid 206 of the oven 202 is closed to seal the bonding fixture 1050 within the oven 202.

At step 1410, the heater 212 elevates and maintains the temperature within the oven 202 to a predefined temperature. In one embodiment, the heater 212 raises the temperature within the oven 202 above the melting point of the bonding material 106. For example, the heater 212 may maintain the oven 202 at a temperature greater than 150 degrees Celsius, such as 180 degrees Celsius. It is contemplated that the temperature will be selected commiserate with the melting temperature of the bonding material 106. It is further understood that the target tubes 102 and backing tube 104 may expand as the temperature of the oven 202 is elevated. The bonding fixture 1050 and the support tube 1102 are adapted to permit thermal expansion of the target tubes 102 and backing tube 104 while maintaining seals at the gaps 108 and the distal ends of the target assembly 100 and concentricity of the target tubes 102.

At optional step 1412, oxides may be removed from the wetted surfaces exposed to the interstitial space 112 between the target tubes 102 and backing tube 104. The removal of the oxidation results in substantially oxide-free wetted surfaces, improves the bonding of the target tubes 102 to the backing tube 104, reduces cracking of the target tubes 102 during the lifetime of the target assembly 100, and raises the durability of the target assembly 100. In one embodiment, the oxide removal process may be performed by applying an electrical current across the target tubes 102 and backing tube 104 during the bonding step 1414. In another embodiment, the oxide removal step may be performed using a hydrogen reduction reaction by introducing a hydrogen or hydrogen-containing gas mixture into the interstitial space 112 from the gas source 230. In yet another embodiment, oxides may be removed from the wetted surfaces by flushing the interstitial space 112 with additional bonding material 106 or by mechanically rotating the target tubes 102 relative to the backing tube 104.

At step 1414, the target tubes 102 are bonded to the backing tube 104 by opening the inlet valve 244 to allow bonding material in the hopper 246 to fill the interstitial space 112 between the target tubes 102 and the backing tube 104. In one embodiment, the vacuum source 228 is fluidly coupled to the interstitial space 112 through the lower end fitting 1108 to draw a vacuum and pull the bonding material 106 into the interstitial space 112. During step 1414, an observer may optionally monitor the target assembly 100 through the windows 1104 of the support tube 1102 to determine whether any bonding material 106 is leaking through the gaps 108. Once the interstitial space 112 has been filled with bonding material 106, the inlet valve 244 may be closed and the oven 202 is permitted to cool.

At step 1416, after the target assembly 100 has sufficiently cooled, the oven 202 is opened and the bonding fixture 1050 and bonded target assembly 100 are removed from the oven 202. The bonding fixture 1050 is dismantled and removed from the bonded cylindrical target assembly 100.

In another embodiment, the optional spacer 110 may be removed from the target tube assembly 100 at step 1418. The removal of the optional spacer 110 results in the ends 114 of the target tubes 102 being substantially free of any bonding material 106. Ends 114 of target tubes 102 with substantially no bonding material 106 reduces micro arcing between the target tubes 102. Furthermore, removal of the optional spacer 110 eliminates the need to remove the bonding material 106 from the ends 114 of the target tubes 102. Thus, the ends 114 of the target tubes 102 are free of any tool-marks which may lead to chipping of the target tubes 102 during use.

Thus a method and apparatus have been discussed above which advantageously produces a cylindrical sputtering target assembly with little or no oxide present in the bonding material. The cylindrical sputtering target assembly of one embodiment of the present invention has an improved bond between the target tubes 102 and backing tube 104 which results in a decreased likelihood of cracking of the target tubes 102 while extending the lifespan of the target assembly 100. The cylindrical sputtering target of one embodiment of the present invention has an improved concentricity of the bonding material 106 in the interstitial space 112 which results in decreased residue of the bonding material 106 on the ends 114 of the target tubes 102. The ends 114 of the target tubes 102 are free of the bonding material 106 without any tool marks, yielding a target assembly with a minimal probability of micro arcing. The cylindrical sputtering target assembly of one embodiment of the present invention enables the ends of neighboring target tubes to be consistently and concentrically aligned without bonding material 106 present on the outer surface of the target assembly, yielding a robust target assembly with low contribution to defect rates.

While the foregoing is directed to embodiments of the present invention, other and further embodiments of the invention may be devised without departing from the basic scope thereof, and the scope thereof is determined by the claims that follow.

1. A cylindrical target assembly comprising:
a backing tube;
at least two sputtering target tubes;
an outer wall diameter of the target tubes;
a gap, the gap defined between the target tubes; and
a bonding material securing the target tubes to the backing tube, the bonding material forming a cylindrical surface in the gap, the cylindrical surface substantially concentric to the backing tube and spaced inwards of the outer wall diameter.

2. The cylindrical target assembly of claim 1, further comprising:
ends of the target tubes, wherein the ends are substantially free of bonding material and free of any tool-marks.

3. The cylindrical target assembly of claim 1, wherein the cylindrical surface is substantially smooth.

4. The cylindrical target assembly of claim 1, wherein one or more indents are formed in the cylindrical surface.

5. The cylindrical target assembly of claim 1, further comprising:
a spacer, wherein the spacer fills in the gap.

6. The cylindrical target assembly of claim 1, further comprising:
an interstitial space;
one or more surfaces of the target tubes; and
an outer wall of the target tubes.

7. A method for forming a cylindrical target assembly, comprising:
wetting an inner surface of at least two sputtering target tubes and an outer surface of a backing tube with a bonding material to form wetted surfaces;
disposing the sputtering target tubes around the backing tube, an interstitial space defined between the sputtering target tubes and the backing tube;
filling a gap defined between the sputtering target tubes with a spacer;
bonding the sputtering target tubes to the backing tube by filling the interstitial space with bonding material; and
removing the spacer.

8. The method of claim 7 further comprising:
removing oxides present on the wetted surfaces defining the interstitial space.

9. The method of claim 8, wherein the removing oxides comprises:
applying an electrical bias potential across the sputtering target tubes and the backing tube.

10. The method of claim 8, wherein the removing oxides comprises:
applying a direct current through the sputtering target tubes and the backing tube to drive a reduction reaction.

11. The method of claim 8, wherein the removing oxides comprises:
providing a hydrogen-containing gas mixture to the interstitial space.

12. The method of claim 11, wherein the hydrogen-containing gas mixture comprises less than about 3 percent hydrogen gas by weight

13. The method of claim 8, where the removing oxides comprises:
flushing the interstitial space with additional bonding material.

14. The method of claim 8, where the removing oxides comprises:
mechanically rotating the sputtering target tubes relative to the backing tube.

15. An apparatus for fabricating a cylindrical target assembly, comprising:
a support tube having an inside diameter;
two end fittings having an inner diameter less than the inside diameter of the support tube, each end fitting having a passage extending from an outer diameter to the inner diameter; and
a plurality of clamp elements operable to clamp the support tube between the two end fittings.

16. The apparatus of claim 15, wherein the support tube comprises a plurality of windows formed through the support tube.

17. The apparatus of claim 16, wherein the plurality of windows are evenly spaced.

18. The apparatus of claim 15, wherein each end fitting comprises:
a large inner diameter coupled to the inner diameter by a step, the large inner diameter having a diameter greater than the diameter of the support tube.

19. The apparatus of claim 18, wherein each end fitting comprises:
a first o-ring gland formed in the large inner diameter and a second o-ring gland formed in the inner diameter, the passage disposed between the first and second o-ring glands.

20. The apparatus of claim 15, wherein the support tube is fabricated from aluminum or polyvinyl chloride (PVC).
